(19) United States
(12) Patent Application Publication
(10) Pub. No.: US 2024/0128336 A1
(43) Pub. Date: Apr. 18, 2024

(54) METHODS OF FORMING SEMICONDUCTOR STRUCTURES AND RESULTING SEMICONDUCTOR STRUCTURES

(71) Applicant: Wolfspeed, Inc., Durham, NC (US)

(72) Inventor: Christer Hallin, Hillsborough, NC (US)

(21) Appl. No.: 17/966,081

(22) Filed: Oct. 14, 2022

(51) Int. Cl. H01L 29/417; H01L 21/02; H01L 21/285; H01L 21/306; H01L 21/308; H01L 21/78; H01L 29/20; H01L 29/205; H01L 29/66; H01L 29/778

(52) U.S. Cl. CPC H01L 29/4175; H01L 21/0254; H01L 21/02639; H01L 21/28575; H01L 21/30617; H01L 21/308; H01L 21/78; H01L 29/2003; H01L 29/205; H01L 29/66462; H01L 29/7786

(57) ABSTRACT

A method of forming a semiconductor structure includes forming an epitaxial semiconductor island having a first material characteristic on a base layer, and growing an epitaxial structure from the epitaxial semiconductor island and the base layer. The epitaxial structure has a second material characteristic that is different from the first material characteristic of the epitaxial semiconductor island. Related semiconductor device structures are also disclosed.

### BACKGROUND

The present disclosure relates to semiconductor device structures and in particular to III-nitride devices having ohmic contacts.

Narrow bandgap semiconductor materials, such as silicon (Si) and gallium arsenide (GaAs), are widely used in semiconductor devices for low power and, in the case of Si, low frequency applications. However, these semiconductor materials may not be well-suited for high power and/or high frequency applications, for example, due to their relatively small bandgaps (1.12 eV for Si and 1.42 for GaAs at room temperature) and relatively small breakdown voltages.

Interest in high power, high temperature and/or high frequency applications and devices has focused on wide bandgap semiconductor materials such as silicon carbide (3.2 eV for 4H—SiC at room temperature) and the Group III nitrides (e.g., 3.36 eV for GaN at room temperature). Group III-nitrides, or III-nitrides, are compound semiconductor materials that include nitride and an element from Group III of the periodic table, such as Ga, Al or In. Group III-nitride materials and SiC may have higher electric field breakdown strengths and higher electron saturation velocities than GaAs and Si.

FIG. 1 shows a conventional GaN-based high electron mobility transistor (HEMT) 10 formed on a silicon carbide substrate 12. A GaN channel layer 16 is on the substrate 12, and an AlGaN barrier layer 18 is on the channel layer 16. A two-dimensional electron gas (2DEG) 20 arises in the channel layer 16 adjacent the barrier layer 18. A source ohmic contact 22 and a drain ohmic contact 24 are formed on the channel layer 16. The conductivity of the 2DEG 20 is modulated by applying a voltage to a gate 26 that is formed on the barrier layer 18 between the source ohmic contact 22 and the drain ohmic contact 24. Although illustrated as being formed on the channel layer 16, the source ohmic contact 22 and the drain ohmic contact 24 may extend into the channel layer 16. Moreover, doped contact regions may be formed in the channel layer 16 via ion implantation, and the source ohmic contact 22 and the drain ohmic contact 24 may be formed on the doped contact regions.

As shown in FIG. 1, the gate 26 may have a mushroom or T-top configuration in which the gate 26 contacts the barrier layer 18 in a relatively narrow contact region that extends through a surface dielectric layer 25. A protective dielectric layer 21 covers the entire structure.

To create good ohmic contact areas in III-nitride HEMT structures usually involves high temperature treatments, as annealing and/or epitaxial growth or implantation of highly doped material after the epitaxial layers that form the active region have been grown. These high temperature process steps can be at temperatures as high or even higher than the growth temperature of the active layers. This may lead to deterioration of the thin epitaxial layers of the active region through diffusion of atoms and dislocations, creating rougher interfaces which may reduce the electron mobility of the transistor.

### SUMMARY

A method of forming a semiconductor structure includes forming an epitaxial semiconductor island having a first material characteristic on a base layer, and growing an epitaxial structure from the epitaxial semiconductor island and the base layer. The epitaxial structure has a second material characteristic that is different from the first material characteristic of the epitaxial semiconductor island. The method may further include forming an ohmic contact on the epitaxial semiconductor island.

The epitaxial semiconductor islands may form isolation structures of a semiconductor device including the semiconductor structure. In some embodiments, the epitaxial semiconductor islands form a part of the active region of the semiconductor device.

The epitaxial semiconductor islands may form a p-n junction with the epitaxial structure.

In some embodiments, the first material characteristic comprises a first doping concentration and the second material characteristic comprises a second doping concentration that is different from the first doping concentration.

In some embodiments, the first material characteristic comprises a first conductivity type and the second material characteristic comprises a second conductivity type that is different from the first conductivity type.

In some embodiments, the first material characteristic comprises a first alloy composition and the second material characteristic comprises a second alloy composition that is different from the first alloy composition.

In some embodiments, the epitaxial structure includes a high electron mobility transistor device structure having a channel layer and a barrier layer on the channel layer. The barrier layer has a higher bandgap than the channel layer, such that a two dimensional electron gas (2DEG) is formed at an interface between the channel layer and the barrier layer.

The epitaxial semiconductor island may include a mesa that extends above the base layer, and the 2DEG may have a curvature such that the 2DEG extends up a sidewall of the mesa.

Forming the epitaxial semiconductor islands may include forming a silicon nitride layer on the base layer, forming an opening in the silicon nitride layer to expose a region of the base layer, wherein the epitaxial semiconductor island is formed in the opening, and removing the silicon nitride layer after forming the epitaxial semiconductor island.

The method may further include, after forming the opening in the silicon nitride layer, etching the base layer through the opening in the silicon nitride layer to form a trench in the base layer, wherein the epitaxial semiconductor island is at least partially formed in the trench. Etching the silicon carbide layer may be performed using a reactive ion etch.

The silicon nitride layer may include a high purity nitride layer, and may be formed using low pressure metal organic chemical vapor deposition.

The method may further include selectively etching the epitaxial structure to expose the epitaxial semiconductor island before forming the ohmic contact on the epitaxial semiconductor island. Selectively etching the epitaxial structure to expose the epitaxial semiconductor island may include forming an etch mask on the epitaxial structure having an opening therein above the epitaxial semiconductor island, and etching the epitaxial structure through the opening in the etch mask.

The method may further include forming a nucleation layer on the exposed region of the base layer before growing the epitaxial semiconductor island on the base layer. The nucleation layer may include aluminum nitride.

The base layer may be a silicon carbide layer. The epitaxial structure may include a group III-nitride-based epitaxial structure.

The base layer may be a bulk substrate wafer, and the method may further include forming a plurality of epitaxial semiconductor islands on the base layer, epitaxially growing a plurality of epitaxial structures across the base layer, wherein the plurality of epitaxial structures correspond to different semiconductor devices, forming a plurality of ohmic contacts to the plurality of epitaxial semiconductor islands, and singulating the bulk substrate wafer to provide individual semiconductor devices.

A semiconductor device structure according to some embodiments includes a substrate, an epitaxial structure on the substrate, and a semiconductor region on the substrate adjacent the epitaxial structure, wherein the semiconductor region extends above the substrate, and wherein the epitaxial structure has a curvature such that the epitaxial structure extends up a sidewall of the semiconductor region.

The epitaxial structure may include a channel layer on the substrate and a barrier layer on the channel layer, wherein the barrier layer has a higher bandgap than the channel layer, such that a 2DEG is formed at an interface between the channel layer and the barrier layer, and the 2DEG may have a curvature such that the 2DEG extends up the sidewall of the semiconductor region.

The channel layer, the barrier layer and the semiconductor region may include group III-nitride based semiconductor materials. The substrate may include silicon carbide.

The substrate may include a trench therein, wherein the semiconductor region is at least partially formed in the trench.

The semiconductor region may include gallium nitride and may be doped with n-type dopants.

A semiconductor device according to some embodiments includes a substrate, an epitaxial semiconductor island on the substrate comprising a first material characteristic, and a semiconductor region comprising a second material characteristic different from the first material characteristic and grown from the substrate and from the epitaxial semiconductor island. The epitaxial semiconductor island extends to, contacts, or forms a part of, an active region of the semiconductor device.

A semiconductor wafer according to some embodiments includes a plurality of epitaxial semiconductor islands on an upper surface of the semiconductor wafer and comprising a first material characteristic. The plurality of epitaxial semiconductor islands are laterally spaced from one another along the upper surface of the semiconductor wafer and are configured such that semiconductor devices are formed from epitaxial material with at least one second material characteristic different from the first material characteristic that is grown between the epitaxial semiconductor islands and on the semiconductor wafer and extend to, contact or form a part of active structures of the semiconductor devices.

### BRIEF DESCRIPTION OF THE DRAWINGS

FIG. 1 illustrates a conventional GaN-based high electron mobility transistor structure.

FIG. 2 illustrates a GaN-based high electron mobility transistor structure according to some embodiments.

FIGS. 3A to 31 illustrate operations for forming ohmic contacts according to some embodiments.

FIGS. 4A to 4H illustrate operations for forming ohmic contacts according to some embodiments.

FIG. 5 is a flowchart illustrating operations according to some embodiments.

FIGS. 6A, 6B and 6C are schematic block diagrams of multi-amplifier circuits in which RF transistor amplifiers incorporating transistor devices according to embodiments may be used.

FIG. 7 is a schematic illustration of a MMIC amplifier including a HEMT transistor according to some embodiments.

FIGS. 8A and 8B are schematic cross-sectional views illustrating example packages for RF transistor amplifier dies according to some embodiments.

FIG. 9 illustrates a bulk substrate wafer on which a plurality of semiconductor devices are formed according to some embodiments.

FIG. 10 illustrates some examples of shapes of epitaxial semiconductor islands formed according to some embodiments.

FIG. 11 illustrate some examples of shapes of recesses in which epitaxial semiconductor islands formed according to some embodiments.

FIG. 12 illustrate some examples of shapes of epitaxial semiconductor islands formed according to some embodiments.

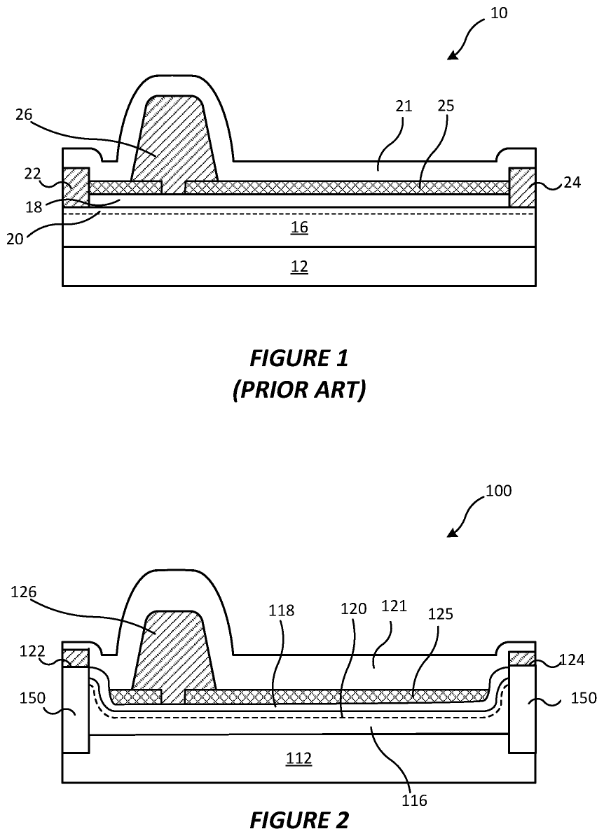

### DETAILED DESCRIPTION OF EMBODIMENTS

Embodiments of the inventive concepts will now be described in connection with the accompanying drawings.

Some embodiments described herein provide doped contact regions in a III-nitride structure formed on a SiC substrate that are grown before the active regions are grown. Typically, the epitaxial layers for a device structure are all grown on top of a substrate. Some embodiments described herein form doped contact regions of the device structure in pre-etched areas in the substrate. The non-etched areas are protected from growth by, for example, a SiN or SiOx mask. The doped areas are defined in the etched portions of the SiC substrate, since GaN does not nucleate and grow on SiN or SiOx.

Growth of the III-nitride epitaxial structure is primarily accomplished through lateral epitaxial growth, which promotes lower dislocation density in the epitaxial structure. Moreover, in some embodiments, the doped contact regions are formed as mesas or semiconductor islands that extend from the substrate. Because the epitaxial layers are grown after formation of the mesa contact regions, the channel region of the epitaxial structure may conform to a sidewall of the mesa contact region, which may reduce a contact resistance of the device.

FIG. 2 shows a GaN-based high electron mobility transistor (HEMT) 100 formed on a silicon carbide substrate 112. A GaN channel layer 116 is on the substrate 112, and an AlGaN barrier layer 118 is on the channel layer 116. The channel layer 116 and the barrier layer 118 may be formed as undoped (or unintentionally doped) semiconductor layers. A two-dimensional electron gas (2DEG) 120 arises in the channel layer 116 adjacent the barrier layer 118.

A gate 126, which may have a mushroom or T-top configuration, contacts the barrier layer 118 in a relatively narrow contact region that extends through a surface dielectric layer 125. A protective dielectric layer 121 covers the entire structure.

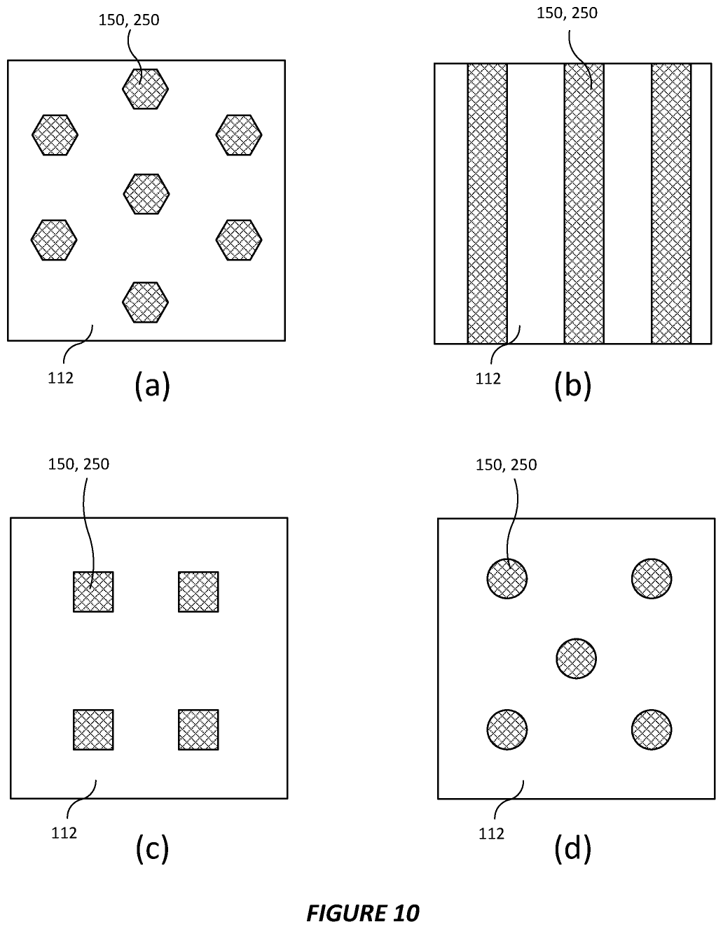

A pair of contact semiconductor islands are formed as epitaxial semiconductor islands 150 on the substrate 112, and the channel layer 116 and barrier layer 118 are formed between the epitaxial semiconductor islands 150. The epitaxial semiconductor islands 150 include n-type GaN, and are formed as described in more detail below. The epitaxial semiconductor islands 150, which are epitaxially grown semiconductor regions that are raised above the upper surface of the substrate 112, may also be referred to as “semiconductor islands”, “mesas” or similar terminology. As discussed below in connection with FIG. 10, the epitaxial semiconductor islands 150 may have various peripheral shapes, and may in some cases by stripes or other shapes that extend across the entire surface of the substrate 112.

A source ohmic contact 122 and a drain ohmic contact 124 are formed on respective ones of the epitaxial semiconductor islands 150.

As shown in FIG. 2, the channel layer 116 and the barrier layer 118 are conformally formed on inner sidewalls of the epitaxial semiconductor islands 150, such that they extend up the sidewalls of the epitaxial semiconductor islands 150. The 2DEG 120 follows the shape of the channel layer 116 and the barrier layer 118, such that the 2DEG 120 also extends up the sidewalls of the epitaxial semiconductor islands 150, placing the 2DEG in close proximity to the epitaxial semiconductor islands 150 over much of the height of the epitaxial semiconductor islands 150. The proximity between the epitaxial semiconductor islands 150 and the 2DEG 120 may reduce the contact resistance of the source ohmic contact 122 and the drain ohmic contact 124.′

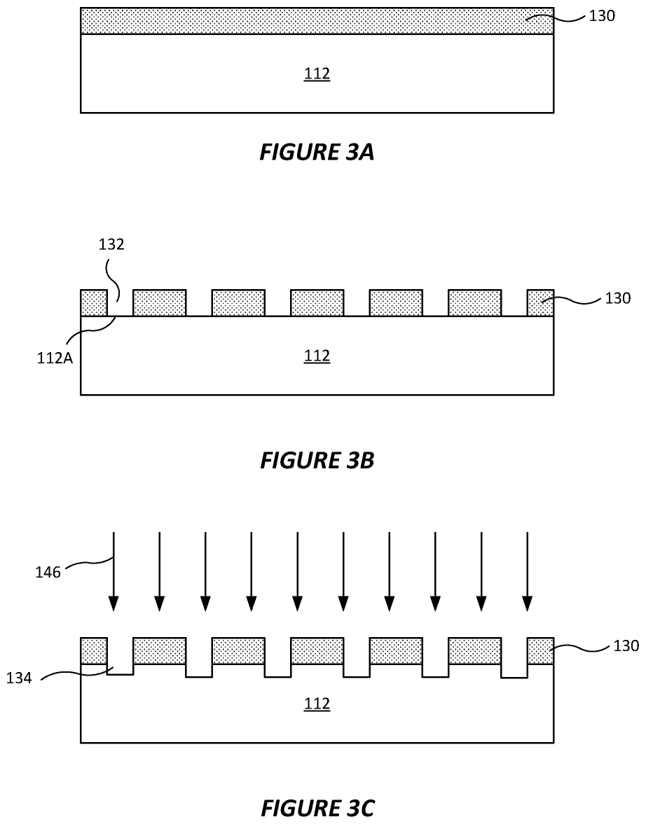

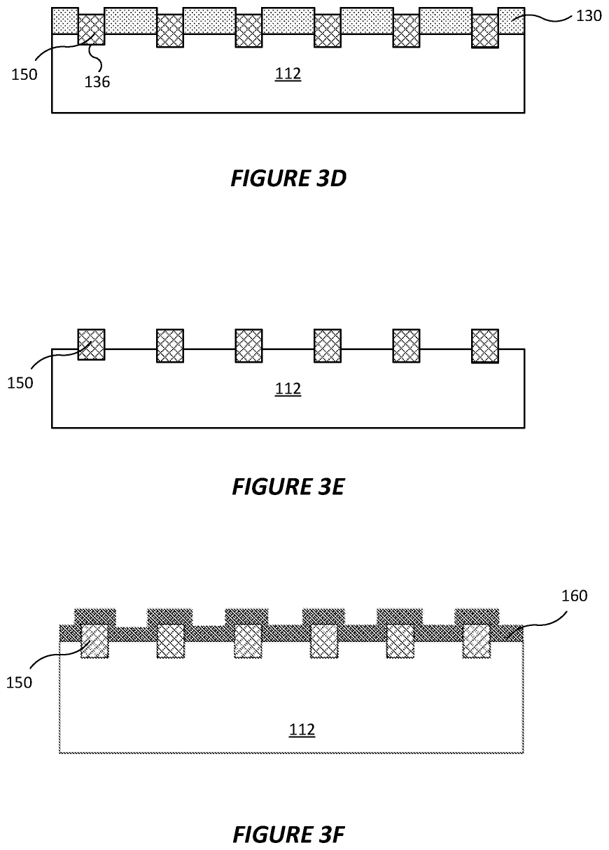

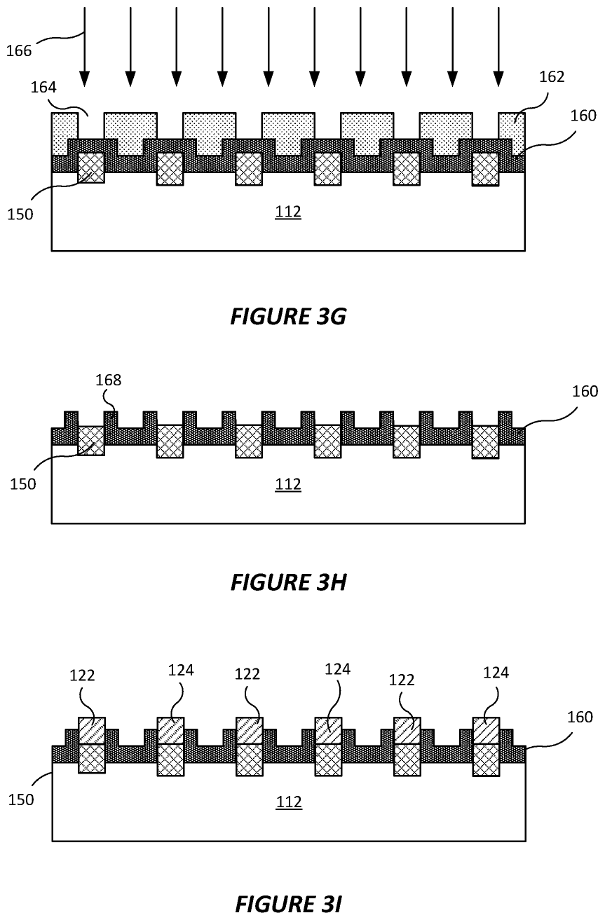

FIGS. 3A to 31 illustrate operations for forming ohmic contacts, such as the source ohmic contact 122 and the drain ohmic contact 124 of FIG. 2, according to some embodiments.

Referring to FIG. 3A, a silicon carbide layer 112 is provided. In some embodiments, the silicon carbide layer 112 may be a bulk silicon carbide substrate having a 2H, 4H, 6H or 3C polytype, and may have an off-angle orientation of about 0 to 5 degrees from, e.g., the (0001) or (000-1) plane. The off-angle orientation may be towards the <11-20> or <1-100> direction.

A mask 130 is formed on the silicon carbide layer 112. The mask 130 may be a layer of high purity silicon nitride (HPN), and may be formed, for example, in a metal-organic chemical vapor deposition reactor (MOCVD). The mask 130 may be formed from other materials, such as SiOx or any other suitable mask material. In some embodiments, the mask 130 may be formed through LPCVD (low pressure chemical vapor deposition) or PECVD (plasma enhanced chemical vapor deposition). The mask 130 may have a thickness of about 10 nm to 500 nm.

Referring to FIG. 3B, openings 132 may be formed in the mask 130 to expose portions 112A of the silicon carbide layer 112.

Referring to FIG. 3C, an isotropic or anisotropic etch process 146 is performed through the openings in the mask 130 to etch a plurality of trenches or recesses 134 in the silicon carbide layer 112. The recesses 134 may be formed to a depth of between about zero to 600 nm. The etch process 146 may, for example, be a reactive ion etch (RIE) process.

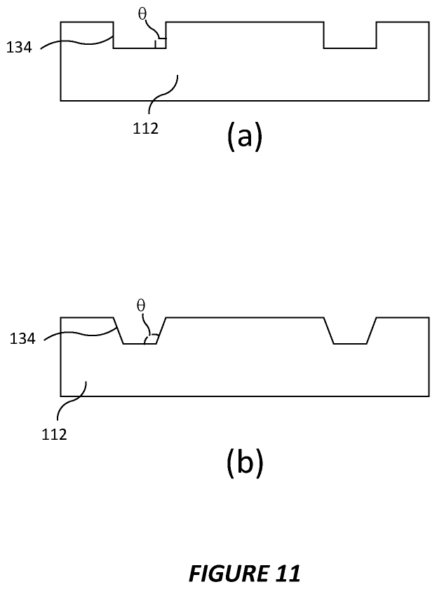

Referring briefly to FIG. 11, the sidewalls of the recesses 134 may form a 90° angle θ with the bottom sides of the recesses 134 in some embodiments. However, in some embodiments, the sidewalls of the recesses 134 may form an angle θ with the bottom sides that is greater than 90°. For example, in some embodiments, the sidewalls of the recesses 134 may form an angle θ with the bottom surfaces of the recesses 134 that is up to about 125°.

Referring to FIG. 3D, a plurality of epitaxial semiconductor islands 150 are grown in the recesses 134, for example, by metal-organic chemical vapor deposition (MOCVD). The epitaxial semiconductor islands 150 may include a group III-nitride material such as gallium nitride. Brief reference is made to FIGS. 10 and 11, which illustrates a silicon carbide layer 112 in plan view (FIG. 10) and side view (FIG. 11) with epitaxial semiconductor islands 150, 250 having various shapes formed thereon. For example, as shown in plan view in FIG. 10, the epitaxial semiconductor islands 150, 250 may be formed for example in the shape of hexagons (FIG. 10(a)), stripes (FIG. 10(b)), quadrilaterals (FIG. 10(c)), or circles (FIG. 10(d)). The examples shown in FIG. 10 are not exhaustive, and the epitaxial semiconductor islands 150, 250 may be formed in other shapes in addition to those shown in FIG. 10.

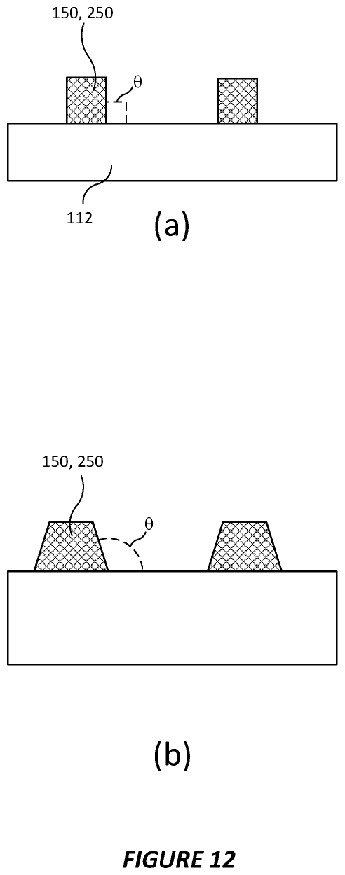

Referring briefly to FIG. 12, the sidewalls of the epitaxial semiconductor islands 150, 250 may form a 90° angle θ with the semiconductor layer 112 in some embodiments. However, in some embodiments, the sidewalls of the epitaxial semiconductor islands 150, 250 may form an angle θ with the semiconductor layer 112 that is greater than 90°. For example, in some embodiments, the sidewalls of the epitaxial semiconductor islands 150, 250 may form an angle θ with the semiconductor layer 112 that is up to about 125°.

Referring again to FIG. 3D, In some embodiments, a nucleation layer 136 of aluminum nitride may be grown in the recesses 134 prior to growth of the epitaxial semiconductor islands 150 to promote nucleation and growth of the epitaxial semiconductor islands 150. The epitaxial semiconductor islands 150 preferentially form within the recesses 134, and do not substantially nucleate on the mask 130. The epitaxial semiconductor islands 150 are doped with an n-type dopant, such as silicon. In some embodiments, the epitaxial semiconductor islands 150 may have a doping concentration of about 1E16 cm⁻³ to about 1E20 cm⁻³.

Referring to FIG. 3E, the mask 130 is then removed, for example via a wet etch process, leaving the epitaxial semiconductor islands 150 protruding from the silicon carbide layer 112. Processes for selective etching of silicon nitride are well known in the art.

Referring to FIG. 3F, a device epitaxial structure 160 is grown via MOCVD. In particular, the device epitaxial structure 160 may be grown on the silicon carbide layer 112 and the epitaxial semiconductor islands 150. In addition to epitaxially growing from the silicon carbide layer 112, at least some of the growth of the device epitaxial structure 160 may occur from sidewalls of the epitaxial semiconductor islands 150.

The epitaxial semiconductor islands 150 have a first material characteristic and the device epitaxial structure 160 has a second material characteristic that is different from the first material characteristic. For example, the first material characteristic may be a first doping concentration and the second material characteristic may be a second doping concentration that is different from the first doping concentration. In some embodiments, the epitaxial semiconductor islands 150 may be doped, for example with an n-type dopant, while the device epitaxial structure 160 may be undoped. Conversely, in some embodiments, the device epitaxial structure 160 may be doped, for example with an n-type dopant, while the epitaxial semiconductor islands 150 may be undoped.

In some embodiments, the first material characteristic may be a first conductivity type and the second material characteristic may be a second conductivity type that is different from the first conductivity type. Accordingly, the device epitaxial structure 160 and the epitaxial semiconductor islands 150 may form a P-N junction at an interface thereof.

In some embodiments, the first material characteristic may be a first alloy composition and the second material characteristic may be a second alloy composition. For example, the epitaxial semiconductor islands 150 may include GaN and the device epitaxial structure 160 may include AlGaN, InGaN, AlN, etc.

In some embodiments, the epitaxial semiconductor islands 150 form isolation structures of the semiconductor device. In other embodiments, the epitaxial semiconductor islands 150 form a part of the active region of the semiconductor device (where “active region” refers to the region in the semiconductor device where the current flow through the device is controlled, modulated, and/or activated. In some embodiments, the “active region” of a device includes the epitaxial layers/regions where the current flow through the device is controlled/modulated/activated and does not include the substrate or buffer layers on which the device is formed.

In some embodiments, the device epitaxial structure 160 may include a channel layer 116 and a barrier layer 118 as shown in FIG. 2, which cause a 2DEG 120 to arise at the interface thereof. Because the device epitaxial structure 160 grows at least partially from the sidewalls of the epitaxial semiconductor islands 150, the interface of the barrier layer 118 and the channel 116 that defines the location of the 2DEG 120 may extend up the sidewalls of the epitaxial semiconductor islands 150 as shown in FIG. 2.

Referring to FIG. 3G, a mask 162 is formed on the silicon carbide layer 112 and device epitaxial structure 160. The mask 162 includes openings 164 above the epitaxial semiconductor islands 150. An anisotropic etch process 166 is then performed to remove portions of the device epitaxial structure 160 above the epitaxial semiconductor islands 150.

Referring to FIG. 3H, the mask 162 is then removed, leaving a plurality of device active regions 168 between respective ones of the epitaxial semiconductor islands 150.

Referring to FIG. 31, respective source and drain contacts 122, 124 are then formed on alternating ones of the epitaxial semiconductor islands 150.

Accordingly, in some embodiments, ohmic contacts of a semiconductor device may be formed to semiconductor structures/regions that are epitaxially grown prior to the epitaxial growth of the device epitaxial layers that define the active region of the device. Thus, some embodiments described herein may be contrasted to techniques such as ion implantation, selective growth and epitaxial regrowth that are commonly used for the formation of semiconductor regions on which ohmic contacts are formed. In particular, ion implantation is commonly used to form a highly doped region in a semiconductor layer on which an ohmic contact may be formed. However, ion implantation can cause significant lattice damage to a semiconductor layer and may require high temperature annealing to repair lattice damage and activate the implanted ions. In contrast, in some embodiments, the epitaxial semiconductor islands 150 can be heavily doped with dopants, such as silicon, during epitaxial growth, which may avoid the need for a high temperature activation anneal to activate the dopants and repair lattice damage.

Some embodiments may therefore be used to replace or supplement techniques such as ion implantation, selective growth and epitaxial regrowth for the formation of semiconductor regions of a semiconductor device.

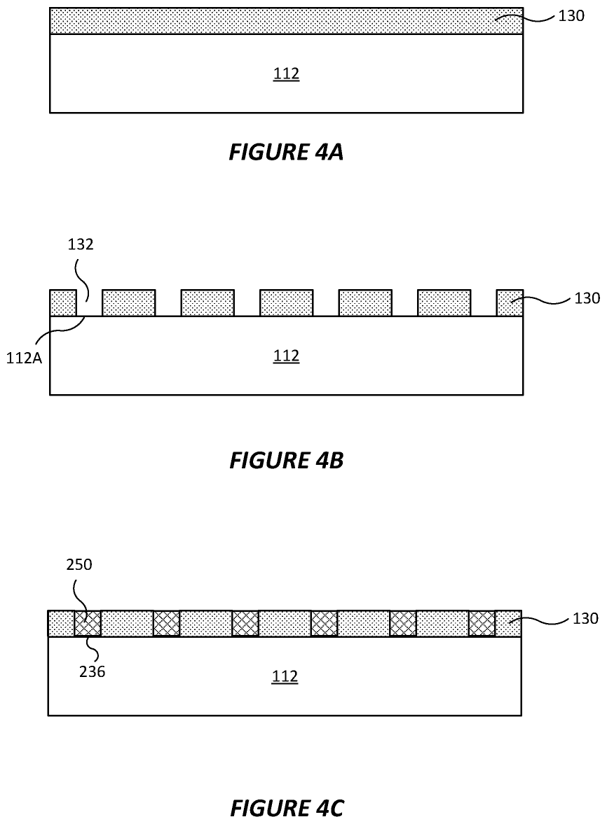

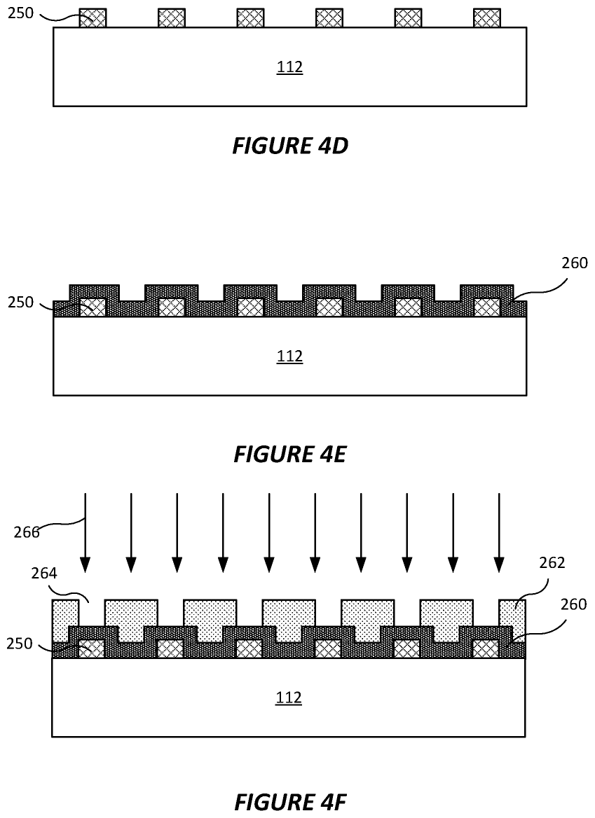

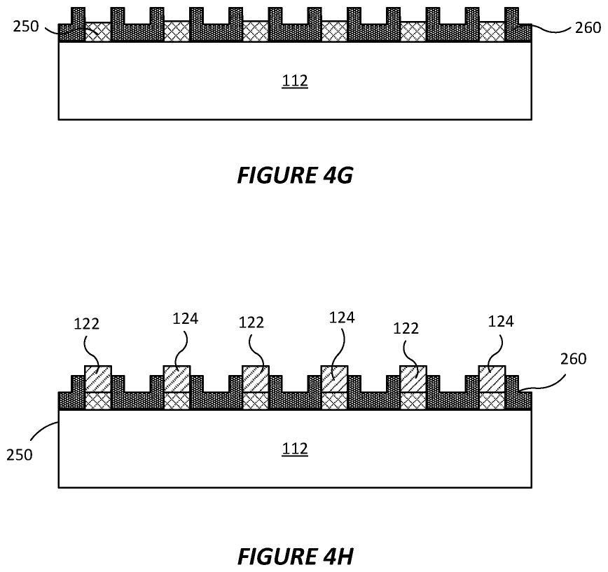

FIGS. 4A to 4I illustrate operations for forming ohmic contacts, such as the source ohmic contact 122 and the drain ohmic contact 124 of FIG. 2, according to some embodiments.

Referring to FIG. 4A, a silicon carbide layer 112 is provided. In some embodiments, the silicon carbide layer 112 may be a bulk silicon carbide substrate having a 2H, 4H, 6H or 3C polytype, and may have an off-angle orientation of about 0 to 5 degrees from, e.g., the (0001) or (000-1) plane. The off-angle orientation may be towards the <11-20> or <1-100> direction.

A mask 130 is formed on the silicon carbide layer 112. The mask 130 may be a layer of high purity silicon nitride (HPN), and may be formed, for example, by lower pressure metal-organic chemical vapor deposition. In some embodiments, the mask 130 may include SiOx or any other suitable material. In some embodiments, the mask 130 may be formed through sputtering. The mask 130 may have a thickness of about 10 nm to 1000 nm.

Referring to FIG. 4B, openings 132 may be formed in the mask 130 to expose portions 112A of the silicon carbide layer 112.

Referring to FIG. 4C, a plurality of epitaxial semiconductor islands 250 are grown on the exposed portions 112A of the silicon carbide layer 112, for example, by metal-organic chemical vapor deposition (MOCVD). In some embodiments, a nucleation layer 236 of aluminum nitride may be grown in the recesses 134 prior to growth of the epitaxial semiconductor islands 250 to promote nucleation and growth of the epitaxial semiconductor islands 250. The epitaxial semiconductor islands 250 preferentially form on the exposed portions 112A of the silicon carbide layer 112, and do not substantially nucleate on the mask 130. The epitaxial semiconductor islands 250 are doped with an n-type dopant, such as silicon. In some embodiments, the epitaxial semiconductor islands 250 may have a doping concentration of about 1E16 cm⁻³ to about 1E20 cm⁻³.

Referring to FIG. 4D, the mask 130 is then removed, for example via a wet etch process that is selective relative to gallium nitride and silicon carbide, leaving the epitaxial semiconductor islands 250 as islands protruding from the silicon carbide layer 112. Processes for selective etching of silicon nitride are well known in the art.

Referring to FIG. 4E, a device epitaxial structure 260 is grown via MOCVD. In particular, the device epitaxial structure 260 may be grown on the silicon carbide layer 112 and the epitaxial semiconductor islands 250. In addition to epitaxially growing from the silicon carbide layer 112, at least some of the growth of the device epitaxial structure 160 may occur from sidewalls of the epitaxial semiconductor islands 250.

The device epitaxial structure 260 may include a channel layer 116 and a barrier layer 118 as shown in FIG. 2, which cause a 2DEG 120 to arise at the interface thereof. Because the device epitaxial structure 260 grows at least partially from the sidewalls of the epitaxial semiconductor islands 250, the interface of the barrier layer 118 and the channel 116 that defines the location of the 2DEG 120 may extend up the sidewalls of the epitaxial semiconductor islands as shown in FIG. 2.

Referring to FIG. 4F, a mask 262 is formed on the silicon carbide layer 112 and device epitaxial structure 260. The mask 262 includes openings 264 above the epitaxial semiconductor islands 250. An anisotropic etch process 266 is then performed to remove portions of the device epitaxial structure 260 above the epitaxial semiconductor islands 250.

Referring to FIG. 4G, the mask 262 is then removed, leaving a plurality of device active regions 168 between respective ones of the epitaxial semiconductor islands 250.

Referring to FIG. 4H, respective source and drain contacts 122, 124 are then formed on alternating ones of the epitaxial semiconductor islands 250.

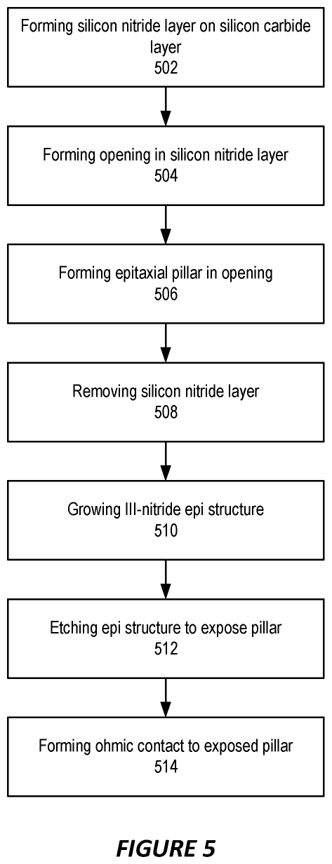

FIG. 5 illustrates operations of forming a semiconductor device structure on a silicon carbide layer according to some embodiments. In particular, a method of forming a semiconductor device structure on a silicon carbide layer according to some embodiments includes forming a mask 130 on the silicon carbide layer (block 502) and forming an opening 132 in the mask 130 to expose a region of the silicon carbide layer (block 504). An epitaxial semiconductor island 150, 250 is formed in the opening in the silicon nitride layer (block 506). The epitaxial semiconductor island comprises a group III-nitride semiconductor material, such as gallium nitride. The epitaxial semiconductor island may be doped, for example, with an n-type dopant such as silicon.

The silicon nitride layer is then removed (block 508) and a group III-nitride-based epitaxial structure 160, 260 is epitaxially grown across the silicon carbide layer. The group III-nitride-based epitaxial structure at least partially grows laterally from the epitaxial semiconductor island across the silicon carbide layer. The group III-nitride-based epitaxial structure is then selectively etched (block 512) the to expose the epitaxial semiconductor island, and an ohmic contact 122, 124 is formed (block 512) on the epitaxial semiconductor island.

Transistor devices as described herein may be used in amplifiers that operate in a wide variety of different frequency bands. In some embodiments, the RF transistor amplifiers incorporating transistor devices as described herein may be configured to operate at frequencies greater than 1 GHz. In other embodiments, the RF transistor amplifiers may be configured to operate at frequencies greater than 2.5 GHz. In still other embodiments, the RF transistor amplifiers may be configured to operate at frequencies greater than 3.1 GHz. In yet additional embodiments, the RF transistor amplifiers may be configured to operate at frequencies greater than 5 GHz. In some embodiments, the RF transistor amplifiers may be configured to operate in at least one of the 2.5-2.7 GHz, 3.4-4.2 GHz, 5.1-5.8 GHz, 12-18 GHz, 18-27 GHz, 27-40 GHz or 40-75 GHz frequency bands or sub-portions thereof.

Although embodiments of the inventive concepts have been discussed above with respect to HEMT devices, it will be understood that the inventive concepts described herein may be applied to other types of semiconductor devices, such as MOSFETs, DMOS transistors, and/or laterally diffused MOS (LDMOS) transistors.

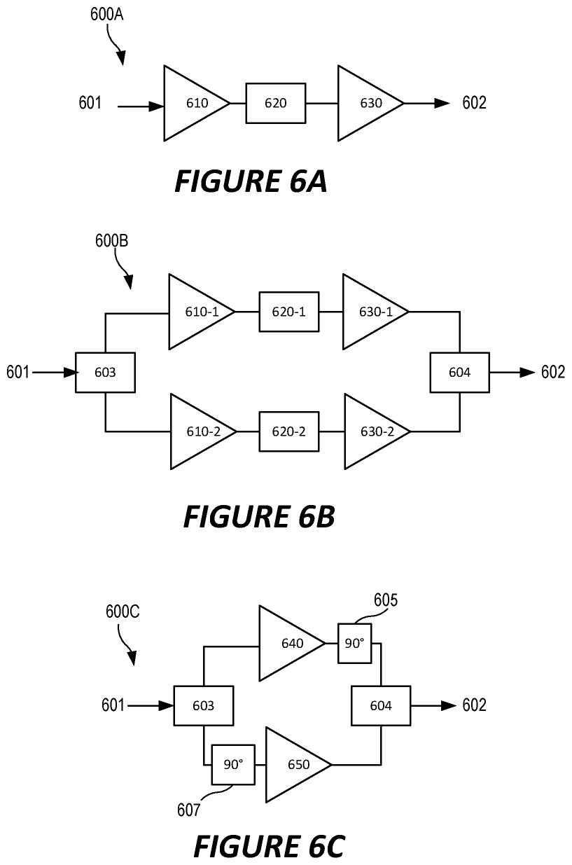

RF transistor amplifiers incorporating transistor devices described herein can be used in standalone RF transistor amplifiers and/or in multiple RF transistor amplifiers. Examples of how the RF transistor amplifiers according to some embodiments may be used in applications that include multiple amplifiers will be discussed with reference to FIGS. 6A-6C.

Referring to FIG. 6A, an RF transistor amplifier 600A is schematically illustrated that includes a pre-amplifier 610 and a main amplifier 630 that are electrically connected in series. As shown in FIG. 6A, RF transistor amplifier 600A includes an RF input 601, the pre-amplifier 610, an inter-stage impedance matching network 620, the main amplifier 630, and an RF output 602. The inter-stage impedance matching network 620 may include, for example, inductors and/or capacitors arranged in any appropriate configuration in order to form a circuit that improves the impedance match between the output of pre-amplifier 610 and the input of main amplifier 630. While not shown in FIG. 6A, RF transistor amplifier 600A may further include an input matching network that is interposed between RF input 601 and pre-amplifier 610, and/or an output matching network that is interposed between the main amplifier 630 and the RF output 602. The RF transistor amplifiers according to embodiments may be used to implement either or both of the pre-amplifier 610 and the main amplifier 630.

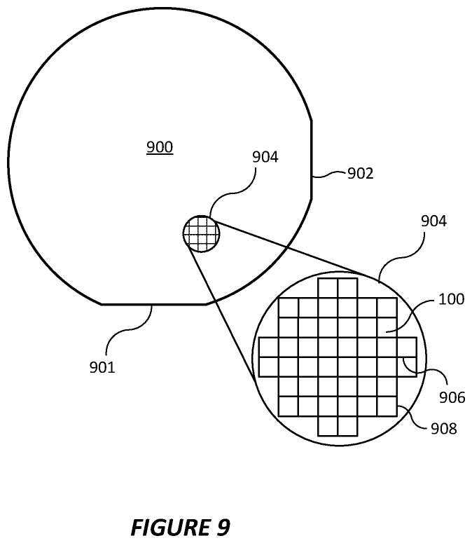

Referring to FIG. 6B, an RF transistor amplifier 600B is schematically illustrated that includes an RF input 601, a pair of pre-amplifiers 610-1, 610-2, a pair of inter-stage impedance matching networks 620-1, 620-2, a pair of main amplifiers 630-1, 630-2, and an RF output 602. A splitter 603 and a combiner 604 are also provided. Pre-amplifier 610-1 and main amplifier 630-1 (which are electrically connected in series) are arranged electrically in parallel with pre-amplifier 610-2 and main amplifier 630-2 (which are electrically connected in series). As with the RF transistor amplifier 600A of FIG. 9A, RF transistor amplifier 600B may further include an input matching network that is interposed between RF input 601 and pre-amplifiers 610-1, 610-2, and/or an output matching network that is interposed between the main amplifiers 630-1, 630-2 and the RF output 602.

As shown in FIG. 6C, the RF transistor amplifiers according to some embodiments may also be used to implement Doherty amplifiers. As is known in the art, a Doherty amplifier circuit includes first and second (or more) power-combined amplifiers. The first amplifier is referred to as the “main” or “carrier” amplifier and the second amplifier is referred to as the “peaking” amplifier. The two amplifiers may be biased differently. For example, the main amplifier may comprise a Class AB or a Class B amplifier while the peaking amplifier may be a Class C amplifier in one common Doherty amplifier implementation. The Doherty amplifier may operate more efficiently than balanced amplifiers when operating at power levels that are backed off from saturation. An RF signal input to a Doherty amplifier is split (e.g., using a quadrature coupler), and the outputs of the two amplifiers are combined. The main amplifier is configured to turn on first (i.e., at lower input power levels) and hence only the main amplifier will operate at lower power levels. As the input power level is increased towards saturation, the peaking amplifier turns on and the input RF signal is split between the main and peaking amplifiers.

As shown in FIG. 6C, the Doherty RF transistor amplifier 600C includes an RF input 601, an input splitter 603, a main amplifier 640, a peaking amplifier 650, an output combiner 604 and an RF output 602. The Doherty RF transistor amplifier 600C includes a 90° transformer 607 at the input of the peaking amplifier 650 and a 90° transformer 606 at the input of the main amplifier 640, and may optionally include input matching networks and/or an output matching networks (not shown). The main amplifier 640 and/or the peaking amplifier 650 may be implemented using any of the above-described RF transistor amplifiers according to embodiments.

The RF transistor amplifiers according to embodiments may be formed as discrete devices, or may be formed as part of a Monolithic Microwave Integrated Circuit (MMIC). A MMIC refers to an integrated circuit that operates on radio and/or microwave frequency signals in which all of the circuitry for a particular function is integrated into a single semiconductor chip. An example MMIC device is a transistor amplifier that includes associated matching circuits, feed networks and the like that are all implemented on a common substrate. MMIC transistor amplifiers typically include a plurality of unit cell HEMT transistors that are connected in parallel.

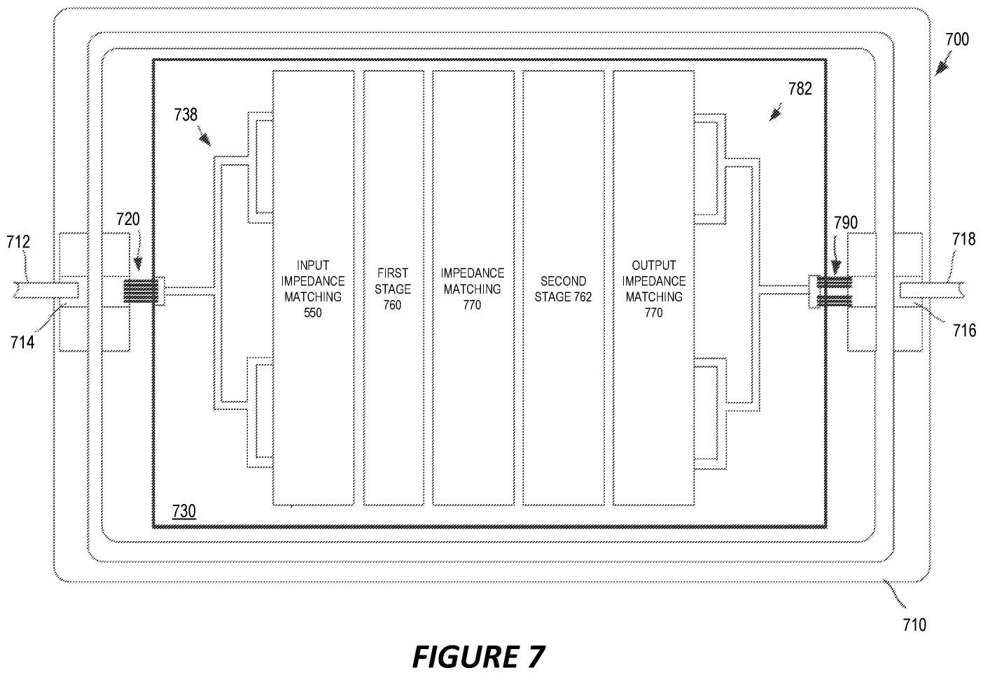

FIG. 7 is a plan view of a MMIC RF transistor amplifier 700 according to embodiments of the present inventive concepts. As shown in FIG. 7, the MMIC RF transistor amplifier 700 includes an integrated circuit chip 730 that is contained within a package 710. The package 710 may comprise a protective housing that surrounds and protects the integrated circuit chip 730. The package 710 may be formed of, for example, a ceramic material.

The package 710 includes an input lead 712 and an output lead 718. The input lead 712 may be mounted to an input lead pad 714 by, for example, soldering. One or more input bond wires 720 may electrically connect the input lead pad 714 to an input bond pad on the integrated circuit chip 730. The integrated circuit chip 730 includes an input feed network 738, an input impedance matching network 750, a first RF transistor amplifier stage 770, an intermediate impedance matching network 770, a second RF transistor amplifier stage 772, an output impedance matching stage 770, and an output feed network 782.

The package 710 further includes an output lead 718 that is connected to an output lead pad 717 by, for example, soldering. One or more output bond wires 790 may electrically connect the output lead pad 717 to an output bond pad on the integrated circuit chip 730. The first RF transistor amplifier stage 770 and/or the second RF transistor amplifier stage 772 may be implemented using any of the RF transistor amplifiers according to embodiments of the present inventive concepts.

The RF transistor amplifiers according to embodiments of the present inventive concepts may be designed to operate in a wide variety of different frequency bands. In some embodiments, these RF transistor amplifier dies may be configured to operate in at least one of the 0.6-2.7 GHz, 3.4-4.2 GHz, 5.1-5.8 GHz, 12-18 GHz, 18-27 GHz, 27-40 GHz or 40-75 GHz frequency bands or sub-portions thereof. The techniques according to embodiments of the present inventive concepts may be particularly advantageous for RF transistor amplifiers that operate at frequencies of 10 GHz and higher.

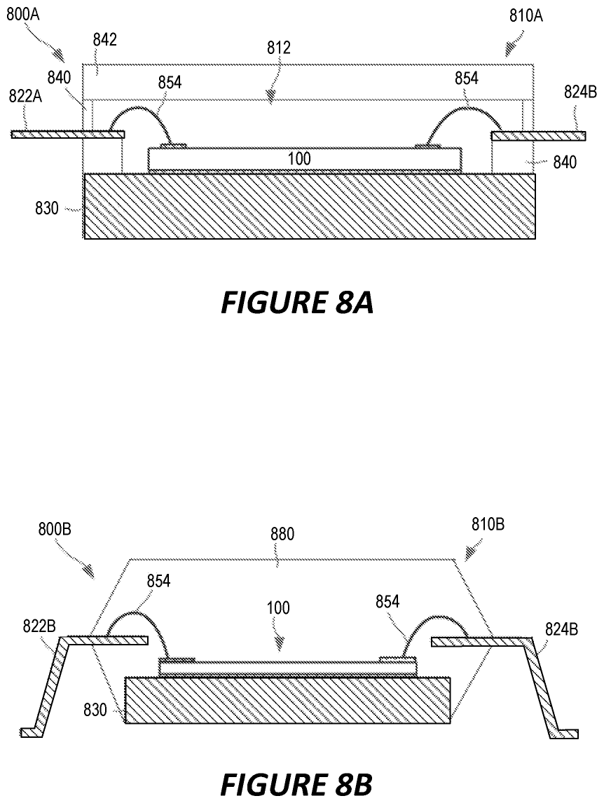

FIGS. 8A and 8B are schematic cross-sectional views illustrating several example ways that that the RF transistor amplifier dies according to embodiments of the present inventive concepts may be packaged to provide packaged RF transistor amplifiers 800A and 800B, respectively.

FIG. 8A is a schematic side view of a packaged Group III nitride-based RF transistor amplifier 800A. As shown in FIG. 8A, packaged RF transistor amplifier 800A includes the RF transistor amplifier die 100 packaged in an open cavity package 810A. The package 810A includes metal gate leads 822A, metal drain leads 824A, a metal submount 830, sidewalls 840 and a lid 842.

The submount 830 may include materials configured to assist with the thermal management of the package 800A. For example, the submount 830 may include copper and/or molybdenum. In some embodiments, the submount 830 may be composed of multiple layers and/or contain vias/interconnects. In an example embodiment, the submount 830 may be a multilayer copper/molybdenum/copper metal flange that comprises a core molybdenum layer with copper cladding layers on either major surface thereof. In some embodiments, the submount 830 may include a metal heat sink that is part of a lead frame or metal slug. The sidewalls 840 and/or lid 842 may be formed of or include an insulating material in some embodiments. For example, the sidewalls 840 and/or lid 842 may be formed of or include ceramic materials.

In some embodiments, the sidewalls 840 and/or lid 842 may be formed of, for example, Al2O3. The lid 842 may be glued to the sidewalls 840 using an epoxy glue. The sidewalls 840 may be attached to the submount 830 via, for example, braising. The gate lead 822A and the drain lead 824A may be configured to extend through the sidewalls 840, though embodiments of the present inventive concepts are not limited thereto.

The RF transistor amplifier die 100 is mounted on the upper surface of the metal submount 830 in an air-filled cavity 812 defined by the metal submount 830, the ceramic sidewalls 840 and the ceramic lid 842. The gate and drain terminals of RF transistor amplifier die 100 may be on the top side of the structure, while the source terminal is on the bottom side of the structure.

The gate lead 822A may be connected to the gate terminal of RF transistor amplifier die 100 by one or more bond wires 854. Similarly, the drain lead 824A may be connected to the drain terminal of RF transistor amplifier die 100 by one or more bond wires 854. The source terminal may be mounted on the metal submount 830 using, for example, a conductive die attach material (not shown). The metal submount 830 may provide the electrical connection to the source terminal 128 and may also serve as a heat dissipation structure that dissipates heat that is generated in the RF transistor amplifier die 100.

The heat is primarily generated in the upper portion of the RF transistor amplifier die 100 where relatively high current densities are generated in, for example, the channel regions of the unit cell transistors. This heat may be transferred though the source vias 148 and the semiconductor layer structure of the device to the source terminal and then to the metal submount 830.

FIG. 8B is a schematic side view of another packaged Group III nitride based RF transistor amplifier 800B. RF transistor amplifier 800B differs from RF transistor amplifier 800A in that it includes a different package 810B. The package 810B includes a metal submount 830, as well as metal gate and drain leads 822B, 824B. RF transistor amplifier 800B also includes a plastic overmold 880 that at least partially surrounds the RF transistor amplifier die 100, the leads 822B, 824B, and the metal submount 830.

FIG. 9 illustrates a bulk substrate wafer 900 on which a plurality of semiconductor devices 100 are formed according to some embodiments. In particular, the bulk substrate wafer 900 may be a 2H, 4H or 6H polytype silicon carbide wafer having a primary flat 901 and a secondary flat 902 indicating the crystallographic orientation of the wafer 900. A representative region 904 of the wafer 900 is shown in magnified view in FIG. 9.

A plurality of semiconductor devices 100 are formed on the wafer 100 according to the methods described above. The semiconductor devices 100 may be singulated by separating the semiconductor devices 100 from the wafer 900. Singulation may be accomplished, for example, by sawing the wafer 900 along horizontal and vertical saw streets 906, 908.

It will be understood that, although the ordinal terms first, second, third, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure.

Furthermore, relative terms, such as “lower” or “bottom” and “upper” or “top,” may be used herein to describe the relationship of one element to another as illustrated in the drawings. It is understood that relative terms are intended to encompass different orientations of the device in addition to the orientation depicted in the drawings. For example, if the device in one of the drawings is turned over, features described as being on the “lower” side of an element would then be oriented on “upper” side of that element. The exemplary term “lower” can therefore describe both lower and upper orientations, depending of the particular orientation of the device. Similarly, if the device in one of the drawings is turned over, elements described as “below” or “beneath” other elements would then be oriented above those other elements. The exemplary terms “below” or “beneath” can therefore describe both an orientation of above and below.

The terminology used in the description of the disclosure herein is for the purpose of describing particular embodiments only and is not intended to be limiting of the disclosure. As used in the description of the disclosure and the appended claims, the singular forms “an” and “the” are intended to include the plural forms as well, unless the context clearly indicates otherwise. It is also understood that the term “and/or” as used herein refers to and encompasses any and all possible combinations of one or more of the associated listed items. It will be further understood that the terms “comprises” and “comprising,” when used in this specification, specify the presence of stated steps, operations, features, elements, and/or components, but do not preclude the presence or addition of one or more other steps, operations, features, elements, components, and/or groups thereof.

Embodiments of the disclosure are described herein with reference to cross-section illustrations that are schematic illustrations of idealized embodiments of the disclosure. As such, variations from the shapes of the illustrations as a result, for example, of manufacturing techniques and/or tolerances, are to be expected. Thus, embodiments of the disclosure should not be construed as limited to the particular shapes of regions illustrated herein but are to include deviations in shapes that result, for example, from manufacturing. The regions illustrated in the drawings are schematic in nature, and their shapes are not intended to illustrate the actual shape of a region of a device and are not intended to limit the scope of the disclosure unless explicitly stated otherwise. Further, lines that appear straight, horizontal, or vertical in the below drawings for schematic reasons will often be sloped, curved, non-horizontal, or non-vertical. Further, while the thicknesses of elements are meant to be schematic in nature.

Unless otherwise defined, all terms used in disclosing embodiments of the disclosure, including technical and scientific terms, have the same meaning as commonly understood by one of ordinary skill in the pertinent art and are not necessarily limited to the specific definitions known at the time of the present disclosure. Accordingly, these terms can include equivalent terms that are created after such time. It is further understood that terms, such as those defined in commonly used dictionaries, should be interpreted as having a meaning that is consistent with their meaning in the present specification and in the context of the relevant art.

Although embodiments of the inventive concepts have been described in considerable detail with reference to certain configurations thereof, other versions are possible. Accordingly, the spirit and scope of the invention should not be limited to the specific embodiments described above.

What is claimed is:

1. A method of forming a semiconductor structure, comprising:
forming an epitaxial semiconductor island comprising a first material characteristic on a substrate; and
growing an epitaxial structure from the epitaxial semiconductor island and the substrate, wherein the epitaxial structure comprises a second material characteristic that is different from the first material characteristic of the epitaxial semiconductor island;
wherein the epitaxial semiconductor island extends to, contacts, or forms a part of, an active region of the semiconductor structure.

2. The method of claim 1, further comprising:
forming an ohmic contact on the epitaxial semiconductor island.

3-11. (canceled)

12. The method of claim 1, wherein the epitaxial structure comprises a high electron mobility transistor device structure having a channel layer and a barrier layer on the channel layer, wherein the barrier layer has a higher bandgap than the channel layer, such that a two-dimensional electron gas, 2DEG, is formed at an interface between the channel layer and the barrier layer.

13. The method of claim 12, wherein the epitaxial semiconductor island comprises a mesa that extends above the substrate, and wherein the 2DEG has a curvature such that the 2DEG extends up a sidewall of the mesa.

14. The method of claim 1, wherein forming the epitaxial semiconductor islands comprises:
forming a mask on the substrate;
forming an opening in the mask to expose a region of the substrate, wherein the epitaxial semiconductor island is formed in the opening; and
removing the mask after forming the epitaxial semiconductor island.

15. The method of claim 14, further comprising, after forming the opening in the mask, etching the substrate through the opening in the mask to form a trench in the substrate, wherein the epitaxial semiconductor island is at least partially formed in the trench.

16-19. (canceled)

20. The method of claim 1, further comprising:
selectively etching the epitaxial structure to expose the epitaxial semiconductor island; and
forming an ohmic contact on the exposed epitaxial semiconductor island.

21. The method of claim 20, wherein selectively etching the epitaxial structure to expose the epitaxial semiconductor island comprises:
forming an etch mask on the epitaxial structure having an opening therein above the epitaxial semiconductor island; and
etching the epitaxial structure through the opening in the etch mask.

22-25. (canceled)

26. The method of claim 1, wherein the substrate comprises a bulk substrate wafer, the method further comprising:
forming a plurality of epitaxial semiconductor islands on the substrate;
epitaxially growing a plurality of epitaxial structures across the substrate, wherein the plurality of epitaxial structures correspond to different semiconductor devices;
forming a plurality of ohmic contacts to the plurality of epitaxial semiconductor islands; and
singulating the bulk substrate wafer to provide individual semiconductor devices.

27. (canceled)

28. A semiconductor device, comprising:
a substrate;
an epitaxial semiconductor island on the substrate comprising a first material characteristic; and
a semiconductor region comprising a second material characteristic different from the first material characteristic and grown from the substrate and from the epitaxial semiconductor island, wherein the epitaxial semiconductor island extends to, contacts, or forms a part of, an active region of the semiconductor device.

29. The semiconductor device of claim 28, further comprising:
an ohmic contact on the semiconductor region, wherein the ohmic contact is conductively coupled to the semiconductor region.

30. The semiconductor device of claim 28, wherein the semiconductor region extends above the substrate, and wherein the epitaxial structure has a curvature such that the epitaxial structure extends up a sidewall of the semiconductor region.

31. The semiconductor device of claim 30, wherein the semiconductor region comprises a first semiconductor region, the semiconductor device further comprising:
a second semiconductor region on the substrate adjacent the epitaxial structure, wherein the second semiconductor region extends above the substrate, and wherein the epitaxial structure has a curvature such that the epitaxial structure extends up a sidewall of the second semiconductor region.

32. The semiconductor device of claim 28, wherein the epitaxial semiconductor island is formed in a recess in an upper surface of the substrate and extends above the upper surface of the substrate.

33-35. (canceled)

36. The semiconductor device of claim 28, wherein the substrate comprises a trench therein, wherein the epitaxial semiconductor island is at least partially formed in the trench.

37-40. (canceled)

41. The semiconductor device of claim 28, wherein the epitaxial semiconductor island forms a part of an active region of the semiconductor device.

42-45. (canceled)

46. A semiconductor wafer comprising the semiconductor of claim 28.

47. A singulated semiconductor device comprising the semiconductor of claim 28.

48. A semiconductor wafer, comprising:
a plurality of epitaxial semiconductor islands on an upper surface of the semiconductor wafer and comprising a first material characteristic;
wherein the plurality of epitaxial semiconductor islands are laterally spaced from one another along the upper surface of the semiconductor wafer and are configured such that semiconductor devices are formed from epitaxial material with at least one second material characteristic different from the first material characteristic that is grown between the epitaxial semiconductor islands and on the semiconductor wafer and extend to, contact or form a part of active structures of the semiconductor devices.

49. The semiconductor wafer of claim 48, further comprising:
a plurality of recesses in the upper surface of the semiconductor wafer, wherein the plurality of epitaxial semiconductor islands are formed in respective ones of the plurality of recesses and extend above the upper surface of the semiconductor wafer.

50-51. (canceled)
